(19) United States
(12) Patent Application Publication
(10) Pub. No.: US 2002/0199144 A1
(43) Pub. Date: Dec. 26, 2002

(54) Scan path test method

(76) Inventor: Hisashi Yamauchi, Tokyo (JP)

Correspondence Address: Darryl G. Walker, WALKER & SAKO, LLP, 300 South First Street, Suite 235, San Jose, CA, 95113, US

(21) Appl. No.: 10/153,014

(22) Filed: May 21, 2002

(30) Foreign Application Priority Data
May 23, 2001 (JP) 2001-153473

(51) Int. Cl. G01R 31/28

(52) U.S. Cl. 714/726

(57) ABSTRACT

A scan test method may include providing initial test values to a plurality of boundary scan flip-flops (231 to 235) in a shift operation mode. In a next clock cycle, next test values may be provided to the plurality of boundary scan flip-flops (231 to 235) in the shift operation mode. A test result may be read from a device under test (241) into a plurality of boundary scan flip-flops (251 and 252) in a normal operation mode. In this way, a test may be conducted on a device under test (241) with only one operation in a normal operation mode and a test pattern may be set with reduced complexity due to normal operating circuits providing test values based on received inputs.

### TECHNICAL FIELD

The present invention relates generally to a test method for an integrated circuit and more particularly to a scan path test method and a circuit for conducting a scan path test.

### BACKGROUND OF THE INVENTION

Generation of scan test patterns with conventional methods can be complicated. For example, one such conventional method of generating a scan test pattern is disclosed in Japanese Patent No. 3090929 (JP '929).

JP '929 loads a pattern into scan registers in a scan path in a shift operation mode. Then, using a normal operation mode, loads input registers with values determined by a combinatorial circuit provided with the outputs of the scan registers. In this way, JP '929 discloses the activation of a test of a circuit under test using a first input pattern (pattern I). However, to generate pattern I, a second input pattern (pattern II) is first scanned into registers. Pattern I is then generated by applying pattern II to the combinatorial circuit. After pattern II is scanned into registers in the shift operation mode, the outputs of scan registers are applied to the combinatorial circuit and the combinatorial circuit generates pattern I as an input to input registers. A clock cycle is then applied to the scan test circuit under a normal operation mode, and pattern I is read into the input registers. Another clock cycle is then applied to obtain the result of the test.

This conventional approach of generating a scan test pattern has the following drawback. Although the test pattern applied to the circuit under test is pattern I, it cannot be directly scanned into the input registers (registers applying the input to the circuit under test). Pattern II, must be scanned into registers and pattern I is then generated by a combinatorial circuit and read into the input registers in the next clock cycle. Thus, it is required that a conventional method set registers in a shift operation mode such that the combinatorial circuit generates the desired values to be latched into the input registers of the circuit under test in the normal operation mode.

For example, FIG. 5 is a circuit schematic diagram for generating a test pattern. A delay test may be performed on a scan path from a scan flip-flop 510 to AND gates (512 and 513) and to a flip-flop 515. When scan flip-flop 510 changes from a zero to a one, scan flip-flops (508 and 509) should each be set to output a one when the first clock is supplied. Further, scan flip-flop 510 should be set to output a zero before the first clock is supplied, and output a one after the first clock is supplied.

By using the conventional method disclosed in JP '929, the values after the first clock are set in a normal operation mode rather than in a shift operation mode. Scan flip-flops (501 to 503) have values set in a shift mode operation, then inverters (504 and 505) and AND gates (506 and 507) provide input values to be read into scan flip-flops (508 to 510) based on the output values of scan flip-flops (501 to 503). The values provided by inverters (504 and 505) and AND gates (506 and 507) are read into scan flip-flops (508 to 510) on the first clock cycle in a normal operation mode.

It is required that the values shifted into scan flip-flops (501 to 503) be determined in consideration of the configuration of a combinatorial circuit (inverters (504 and 505) and AND gates (506 and 507)) in order to set the desired values for scan flip-flops (508 to 510) after the first clock cycle in a normal operation mode.

In the conventional method as disclosed in JP '929, the determination of pattern II necessary to provide the desired pattern I can be complicated.

In view of the above discussion, it would be desirable to provide a test method and circuit that may allow a test, such as a delay test, to be conducted by eliminating a potentially complicated operation caused by using a normal operation mode to generate a test pattern based on an input pattern being applied to a combinatorial circuit. It would also be desirable to provide a test method and circuit that may allow a sequence circuit to be tested without performing potentially complicated settings of normal operation mode circuits.

### SUMMARY OF THE INVENTION

According to the present embodiments, a scan test method may include providing initial test values to a plurality of boundary scan flip-flops in a shift operation mode. In a next clock cycle, next test values may be provided to the plurality of boundary scan flip-flops in the shift operation mode. A test result may be read from a device under test into a plurality of boundary scan flip-flops in a normal operation mode. In this way, a test may be conducted on a device under test with only one operation in a normal operation mode and a test pattern may be set with reduced complexity due to normal operating circuits providing test values based on received inputs.

According to one aspect of the embodiments, a scan test method may be provided for a scan chain of a plurality of scan flip-flops. The plurality of scan flip-flops may include a first plurality of boundary scan flip-flops. The scan test method may include the steps of setting initial test values in the first plurality boundary scan flip-flops through the scan chain in a shift operation mode so that the initial test values may be applied to a circuit under test in a first clock cycle and setting next test values in the first plurality of boundary scan flip-flops in the shift operation mode so that the next test values may be applied to the circuit under test in a next clock cycle. The initial test values and the next test values may be set in successive clock cycles and may be a test pattern for conducting one test.

According to another aspect of the embodiments, the scan test method may include the step of reading a test result into a second plurality of boundary scan flip-flops from the circuit under test in a normal operation mode.

According to another aspect of the embodiments, the scan test method may include the step of shifting data values out of the second plurality of scan flip-flops in the shift operation mode.

According to another aspect of the embodiments, the initial test value may not conflict with the next test values.

According to another aspect of the embodiments, the plurality of scan flip-flops may read data from a scan input in synchronism with a first clock edge in the shift operation mode and may read data from a data input in synchronism with the first clock edge in a normal operation mode.

According to another aspect of the embodiments, the one test may be conducted and a test result may be read into a second plurality of boundary scan flip-flops with only one cycle executed in the normal operation mode.

According to another aspect of the embodiments, a scan test method may be provided for a scan chain. The scan chain may include first and second scan flip-flops and first and second boundary scan flip-flops. The first scan flip-flop may be coupled in the scan chain to provide a first scan flip-flop output to a first boundary scan flip-flop input of the first boundary scan flip-flop. The second scan flip-flop may be coupled in the scan chain to provide a second scan flip-flop output to a second boundary scan flip-flop input of the second boundary scan flip-flop. The scan test method may include the steps of setting initial test values in the first and second boundary scan flip-flops and next test values in the first and second scan flip-flops through the scan chain in a shift operation mode so that the initial test values may be applied to a circuit under test in a first clock cycle and setting the next test values in the first and second boundary scan flip-flops in the shift operation mode so that the next test values may be applied to the circuit under test in a next clock cycle. The initial test values and the next test values may be set in successive clock cycles and may be a test pattern for conducting one test.

According to another aspect of the embodiments, the scan test method may include reading a test result into a third boundary scan flip-flop from the circuit under test in a normal operation mode.

According to another aspect of the embodiments, the scan test method may include shifting a data value out of the third scan flip-flop in the shift operation mode.

According to another aspect of the embodiments of the scan test method, the first boundary scan flip-flop may provide a first boundary scan flip-flop output data to a second scan flip-flop input of the second scan flip-flop.

According to another aspect of the embodiments, the first boundary scan flip-flop may read data from the first boundary scan flip-flop input in synchronism with a first clock edge in the shift operation mode and may read data from a first boundary scan flip-flop data input in synchronism with the first clock edge in a normal operation mode. The second boundary scan flip-flop may read data from the second boundary scan flip-flop input in synchronism with the first clock edge in the shift operation mode and may read data from a second boundary scan flip-flop data input in synchronism with the first clock edge in the normal operation mode. The first scan flip-flop may read data from a first scan flip-flop input in synchronism with the first clock edge in the shift operation mode and may read data from a first scan flip-flop data input in synchronism with the first clock edge in the normal operation mode. The second scan flip-flop may read data from a second scan flip-flop input in synchronism with the first clock edge in the shift operation mode and may read data from a second scan flip-flop data input in synchronism with the first clock edge in the normal operation mode.

According to another aspect of the embodiments, the one test may be conducted and a test result may be read into a third boundary flip-flop with essentially only one clock cycle executed in the normal operation mode.

According to another aspect of the embodiments, a scan test method may be provided for a scan chain. The scan chain may include a plurality of scan flip-flops. The plurality of scan flip-flops may include a first plurality of boundary scan flip-flops. The plurality of scan flip-flops may operate in a shift operation mode and a normal operation mode. The scan method may include the steps of setting initial test values in the first plurality boundary scan flip-flops through the scan chain in a shift operation mode so that the initial test values may be applied to a circuit under test in a first clock cycle, setting next test values in the first plurality of boundary scan flip-flops in the shift operation mode so that the next test values may be applied to the circuit under test in a next clock cycle, and reading a test result from the circuit under test into a second plurality of boundary scan flip-flops in a normal operation mode. The initial test values and the next test values may be set in successive clock cycles and may be a test pattern for conducting one test. The one test may be conducted with essentially only one clock cycle executed in the normal operation mode.

According to another aspect of the embodiments, the next test values may depend on at least a portion of the first test values.

According to another aspect of the embodiments, the next test values may be set in the first plurality of boundary scan flip-flops independent of the first test values.

According to another aspect of the embodiments, the scan test method may further include the step of shifting data values out of the second plurality of scan flip-flops in the shift operation mode.

According to another aspect of the embodiments, the data input to at least one scan flip-flop may be coupled to receive an output from a normal flip-flop.

According to another aspect of the embodiments, the method may test a circuit of a semiconductor memory device.

According to another aspect of the embodiments, the method may test a circuit on a semiconductor device.

According to another aspect of the embodiments, the method may test a circuit on an integrated circuit.

### BRIEF DESCRIPTION OF THE DRAWINGS

FIG. 1 is a timing diagram showing the operation of a scan test circuit according to an embodiment.

FIG. 2 is a circuit schematic diagram of a scan test circuit according to an embodiment.

FIG. 3 is a timing diagram illustrating a conventional circuit test method.

FIG. 4 is a circuit schematic diagram of a scan test circuit according to an embodiment.

FIG. 5 is a circuit schematic diagram for generating a test pattern.

FIG. 6 is a flow chart for a method of generating a test pattern for a typical circuit according to an embodiment.

FIG. 7 is a table illustrating a combining operation according to an embodiment.

FIG. 8 is a circuit schematic diagram of a circuit including a scan test chain according to an embodiment.

FIG. 9 is a circuit schematic diagram of a circuit including a scan test chain according to an embodiment.

### DETAILED DESCRIPTION OF THE EMBODIMENTS

Various embodiments of the present invention will now be described in detail with reference to a number of drawings.

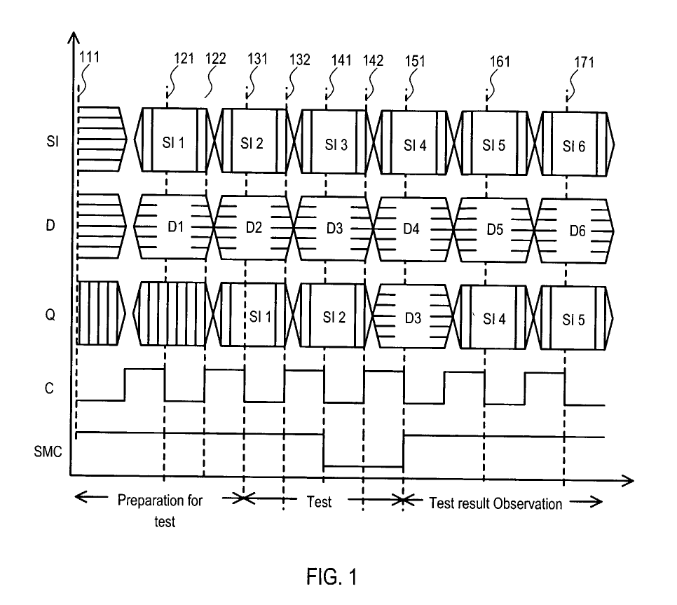

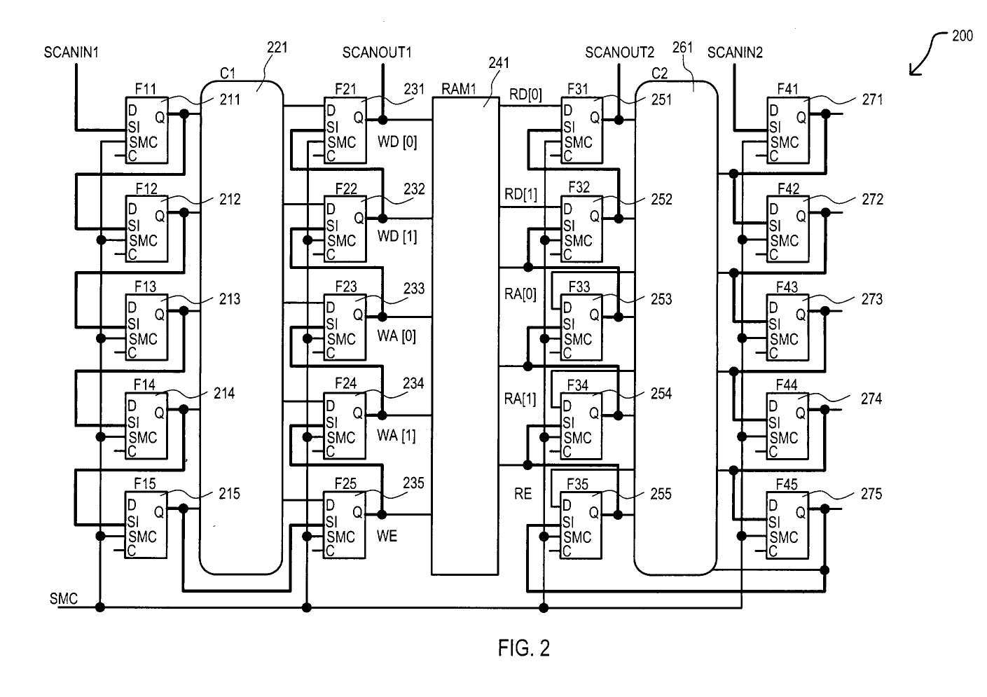

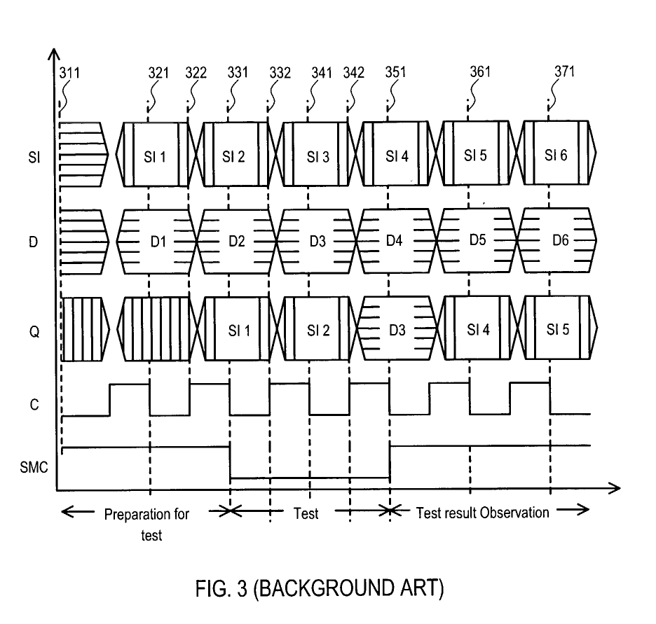

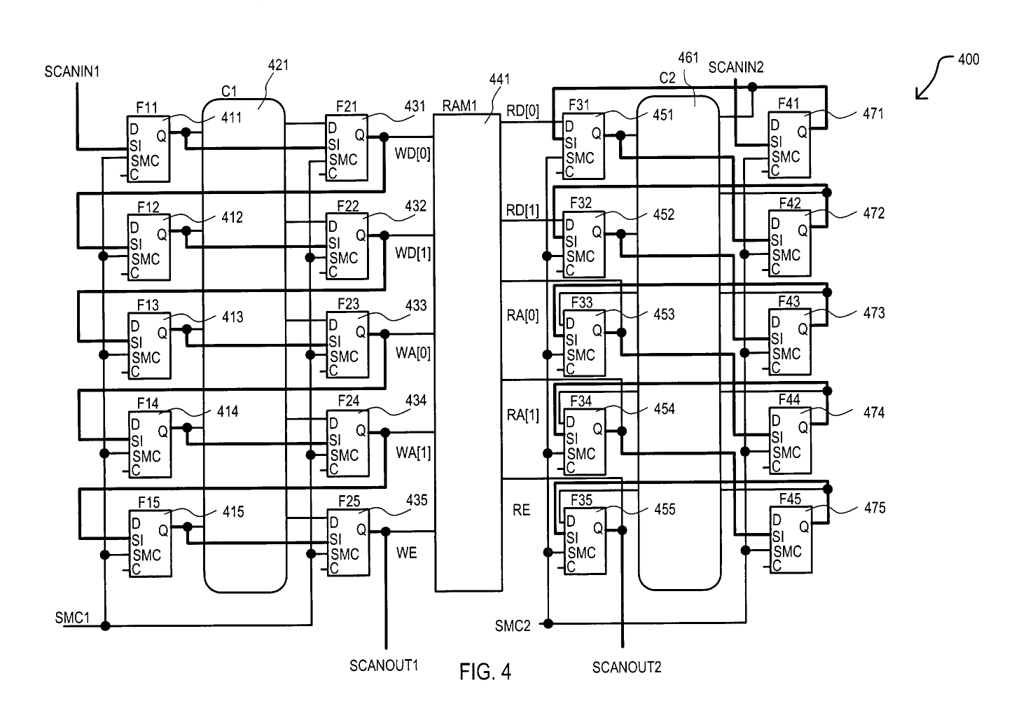

FIG. 1 is a timing diagram illustrating a circuit control method when a circuit test method is conducting according to an embodiment. The timing diagram of FIG. 1 may be applicable to scan test circuits (200 or 400) as illustrated in FIGS. 2 or 4. FIG. 3 is a timing diagram illustrating a conventional circuit test method. The timing diagram of FIG. 3 can be used in a scan test circuit 200 as illustrated in FIG. 2.

Referring now to FIG. 2, a circuit schematic diagram of a scan test circuit 200 according to an embodiment is set forth. Scan test circuit 200 may include scan flip-flops (211 to 215 and 271 to 275) and boundary scan flip flops (231 to 235 and 251 to 255). Scan test circuit 200 may further include normal operation circuits (221 and 261) and a RAM (random access memory) 241 to be tested.

Scan test circuit 200 may be configured such that scan flip-flops (211 to 215) may form a scan chain. Scan chains may be illustrated by bold signal lines. Each scan flip-flop (211 to 215) may provide an output Q to an input of normal operation circuit 221 and to a scan input SI of the next scan flip-flop in the chain. Scan flip-flop 211 may receive a scan input signal SCANIN1 at a scan input SI and may provide an output Q to a scan input SI of the next scan flip-flop 212 in the chain and to normal operation circuit 221. Scan flip-flop 212 may receive an output Q from scan flip-flop 211 at a scan input SI and may provide an output Q to a scan input SI of the next scan flip-flop 213 and to normal operation circuit 221, and so on. Scan flip-flop 215 may provide an output Q to scan flip-flop 235 and normal operation circuit 221.

Scan flip-flops (235 to 231) may form a scan chain. Each scan flip-flop (235 to 231) may provide an output Q to an input of RAM1 241 and to a scan input SI of the next scan flip-flop in the chain. Scan flip-flop 235 may receive an output signal Q from scan flip-flop 215 at a scan input SI and may provide an output Q to a scan input SI of the next scan flip-flop 234 in the chain and to RAM1 241. Scan flip-flop 234 may receive an output signal Q from scan flip-flop 235 at a scan input SI and may provide an output Q to a scan input SI of the next scan flip-flop 233 in the chain and to RAM1 241, and so on. Scan flip-flop 231 may provide an output Q as a scan out signal SCANOUT1 and as an input to RAM1 241. Each scan flip-flop (231 to 235) may receive a respective output from normal operation circuit 221 at a data input D. Scan flip-flops (231 and 232) respectively may provide write data (WD[0] and WD[1]) to RAM1 241. Scan flip-flops (232 and 233) respectively may provide write addresses (WA[0] and WA[1]) to RAM1 241. Scan flip-flop 235 may provide a write enable WE to RAM1 241.

In this way, scan flip-flops (211 to 215 and 235 to 231) may form one scan chain and scan flip-flops (231 to 235) may be considered boundary scan flip-flops.

Scan flip-flops (271 to 275) may form a scan chain. Each scan flip-flop (271 to 275) may provide an output Q to an input of normal operation circuit 261 and to a scan input SI of the next scan flip-flop in the chain. Scan flip-flop 271 may receive a scan input signal SCANIN2 at a scan input SI and may provide an output Q to a scan input SI of the next scan flip-flop 272 in the chain and to normal operation circuit. Scan flip-flop 272 may receive an output Q from scan flip-flop 271 at a scan input SI and may provide an output Q to a scan input SI of the next scan flip-flop 273 and to normal operation circuit 261, and so on. Scan flip-flop 275 may provide an output Q to scan flip-flop 255 and normal operation circuit 261.

Scan flip-flops (255 to 251) may form a scan chain. Scan flip-flop (255 to 253) may provide an output Q to an input of RAM1 241 and to a scan input SI of the next scan flip-flop in the chain. Scan flip-flop 255 may receive an output signal Q from scan flip-flop 275 at a scan input SI and may provide an output Q to a scan input SI of the next scan flip-flop 254 in the chain and to RAM1 241. Scan flip-flop 254 may receive an output signal Q from scan flip-flop 255 at a scan input SI and may provide an output Q to a scan input SI of the next scan flip-flop 253 in the chain and to RAM1 241, and so on. Scan flip-flop 251 may provide an output Q as a scan out signal SCANOUT2 and as an input to RAM1 241. Scan flip-flops (253 and 254) respectively may provide read address signals (RA[0] and RA[1]) to RAM1 241. Scan flip-flop 255 may provide a read enable RE to RAM1 241. Scan flip-flops (253 to 255) may receive data inputs D from normal operation circuit 261. Scan flip-flops (251 and 252) respectively may receive read data (RD[0] and RD[1]) from RAM1 241 and may provide outputs Q to normal operation circuit 261.

In this way, scan flip-flops (271 to 275 and 255 to 251) may form one scan chain and scan flip-flops (251 to 255) may be considered boundary scan flip-flops.

Referring now to FIG. 4, a circuit schematic diagram of a scan test circuit 400 according to an embodiment is set forth. Scan test circuit 400 may include scan flip-flops (411 to 415 and 471 to 475) and boundary scan flip flops (431 to 435 and 451 to 455). Scan test circuit 400 may further include normal operation circuits (421 and 461) and a RAM (random access memory) 441 to be tested.

Scan test circuit 400 may be configured differently than scan test circuit 200 in that a scan chain may be formed by scan flip flops (411 to 415 and 431 to 435) in the order of (411-431-412-432-413-433-414-434-415-435). Scan chains may be illustrated by bold signal lines. Input signal SCANIN1 may be provided to a scan input SI of scan flip-flop 411. Output signal SCANOUT1 may be provided from an output Q of scan flip-flop 435.

A scan chain may also be provided by scan flip-flops (471 to 475 and 451 to 455) in the order of (471-451-472-452-473-453-474-454-475-455). Input signal SCANIN2 may be provided to a scan input SI of scan flip-flop 471. Output signal SCANOUT2 may be provided from an output of scan flip-flop 455.

Scan flip-flops (431 to 435 and 451 to 455) may be considered boundary scan flip-flops.

The timing diagram of FIG. 1 illustrates scan inputs SI, data inputs D, and outputs Q, clock input C, and control input SMC of scan flip-flops (211 to 275 or 411 to 475) in FIGS. 2 and 4. The timing diagram of FIG. 3 illustrates scan inputs SI, data inputs D, and outputs Q, clock input C, and control input SMC of scan flip-flops (211 to 275) in FIG. 2. Control input SMC may control switching between a shift operation mode and a normal operation mode.

Scan flip-flops (211 to 275 or 411 to 475) of FIGS. 2 and 4, may read a value on data input D or scan input SI at a rising edge of clock input C and may provide the read value at output Q. When control input SMC has a logic one (high) value, scan flip-flops (211 to 275 or 411 to 475) may operate in a shift operation mode. When in a shift operating mode, scan flip-flops (211 to 275 or 411 to 475) may read a value on scan input SI at a rising edge of clock input C and may output the read value at output Q. When control input SMC has a logic zero (low) value, scan flip-flops (211 to 275 or 411 to 475) may operate in a normal operation mode. When in a normal operating mode, scan flip-flops (211 to 275 or 411 to 475) may read a value on data input D at a rising edge of clock input C and may output the read value at output Q.

In FIG. 1, clock cycles may include a rising edge of clock input C as represented by reference numbers (122, 132, and 142) and a boundary of a test cycle as represented by reference numbers (111, 121, 131, 141, 151, 161, and 171). Likewise, in FIG. 3, clock cycles may include a rising edge of clock input C as represented by reference numbers (322, 332, and 342) and a boundary of a test cycle as represented by reference numbers (311, 321, 331, 341, 351, 361, and 371).

First, a conventional test method will be described with reference to the timing diagram of FIG. 3 in conjunction with scan test circuit 200 of FIG. 2. FIG. 3 illustrates a case where a delay test is conducted on a RAM 241 of FIG. 2. Cycles before test cycle boundary 111 and after test cycle boundary 171 have been omitted for convenience.

The timing diagram of FIG. 3 may include a preparation for test, a test, and a test result observation. During a preparation for test, a test pattern may be provided into scan flip-flops (211-215 and 271-275) in a shift operation mode (control input SMC is high). This value can represent pattern II as discussed with respect to JP '929.

Next, in accordance with the conventional method, scan test circuit 200 may switch to the normal operation mode (control input SMC becomes low) at test cycle boundary 331. This signals the execution of the test. Scan flip-flops (211 to 215) provide outputs to normal operation circuit 221 (a combinatorial logic circuit). Normal operation circuit 221 provides outputs to scan flip-flops (231 to 235), which are read in at the next rising edge of clock input C. At the same time, scan flip-flops (271 to 275) provide outputs to normal operation circuit 261 (a combinatorial logic circuit). Normal operation circuit 261 provides outputs to scan flip-flops (253 to 255), which are read in at the next rising edge of clock input C. The value read into scan flip-flops (231 to 235) and (253 to 255) can represent pattern I as discussed with respect to JP '929.

Scan flip-flop 231 may provide an output to a write data input WD[0] of RAM1 241. Scan flip-flop 232 may provide an output to a write data input WD[1] of RAM1 241. Scan flip-flop 233 may provide an output to a write address input WA[0] of RAM1 241. Scan flip-flop 234 may provide an output to a write address input WA[1] of RAM1 241. Scan flip-flop 235 may provide an output to a write enable input WE of RAM1 241. Scan flip-flop 253 may provide an output to a read address input RA[0] of RAM1 241. Scan flip-flop 254 may provide an output to a read address input RA[1] of RAM1 241. Scan flip-flop 255 may provide an output to a read enable input RE of RAM1 241.

At this time, RAM 241 operates according to values provided by scan flip-flops (231 to 235 and 253 to 255) and may provide a result at read data outputs (RD[0] and RD[1]), which may be read into scan flip-flops (251 and 252) at the next rising edge of clock input C (time 342).

In this way, it can be seen that the conventional method requires that scan test circuit 200 operates in the normal operation mode for at least two clock cycles. During this time, it is required that normal operation circuits (221 and 261) set values (pattern I) for the test in accordance with receive values (pattern II). In this way, the setting of the desired test pattern (pattern I) can be complicated and errors may be more likely.

Next, at time 351, control input SMC may return high and scan test circuit 200 operates in the shift operation mode. Thus, the test result can be shifted out in subsequent clock cycles for evaluation of the test. It should be noted that scan test circuit 200 may operate using the conventional test method, however, a conventional scan test circuit may be configured differently.

In contrast with the conventional example, the timing diagram of FIG. 1 illustrates a test method according to an embodiment. The test method illustrated in FIG. 1 may be utilized in scan test circuits (200 and 400) of FIGS. 2 and 4.

A test method according to an embodiment will now be discussed with reference to FIG. 1 in conjunction with FIG. 2.

The timing diagram of FIG. 1 may include a preparation for test, a test, and a test result observation.

During a preparation for test, a test pattern may be provided into scan flip-flops (211-215, 235-231, 271-275, and 255-251) in a shift operation mode (control input SMC is high). The values for the test pattern for a delay test, for example, may be read into scan flip-flops synchronously with a rising edge of a clock input C.

At time 132, the test pattern may be applied to boundary scan flip-flops (231 to 235 and 251 to 255) and a test may be executed. At this time, RAM 241 may operate according to values provided by scan flip-flops (231 to 235 and 253 to 255) and may provide a result at read data outputs (RD[0] and RD[1]), which may be read into scan flip-flops (251 and 252) at the next rising edge of clock input C (time 142).

It can be seen that in the test method according to the embodiment of FIG. 1, scan test circuit 200 may operate in the normal operation mode for one clock cycle. A test pattern may be completely set in the shift operation mode. Thus, normal operation circuits (221 and 261) may not be included in a generation of a test pattern in the test method according to the embodiment of FIG. 1. Thus, the complexity of generating a test pattern may be reduced as compared to the conventional approach illustrated in JP '929.

Outputs Q from scan flip-flops (231 and 232) respectively may be a low-order bit and high-order bit of write data (WD[0] and WD[1]). Outputs Q from scan flip-flops (233 and 234) respectively may be a low-order bit and high-order bit of a write address (WA[0] and WA[1]). Output Q from scan flip-flop 235 may be a write enable WE. Outputs Q from scan flip-flops (251 and 252) respectively may be a low-order bit and high-order bit of read data (RD[0] and RD[1]). Outputs Q from scan flip-flops (253 and 254) respectively may be a low-order bit and high-order bit of a read address (RA[0] and RA[1]). Output Q from scan flip-flop 255 may be a read enable RE.

Enable values of write enable WE and read enable RE may both be logic one (high).

In a delay test, first data may be written into a memory cell and then opposite data may then be written into the memory cell. If write data (WD[1]-WD[0]) of (10) is written into an address (WA[1]-WA[0]) of (11) followed by write data (WD[1]-WD[0]) of (11) written to the same address to conduct a delay test, a first test value may be scan-shifted in synchronism with a rising edge of clock input C so that, at timing 122, scan flip-flops (231, 232, 233, 234, and 235) may output (0, 1, 1, 1, and 1), respectively. This may allow write data of (10) to be written into address (11).

A shift operation may continue such that a second test value may be scan-shifted in synchronism with a rising edge of clock input C so that, at timing 132, scan flip-flops (231, 232, 233, 234, and 235) may output (1, 1, 1, 1, and 1), respectively. In this way, write data of (11) to be written into address (11). Also, at timing 132, scan flip-flops (251, 252, 253, 254, and 255) may output (0, 1, 1, 1, and 1), respectively. While a “1” may be set for scan flip-flop 252, by way of example, scan flip-flop 252 may not be required to set to a “1” value because the value of scan flip-flop 252 may not change because desired read data RD [1] may be a “1” in this example.

Values set in scan flip-flops (211 to 275) at times (122 and 132) may be chosen such that a delay test may be performed. In this way, values set in scan flip-flops (211 to 275) at time 122 may not provide contradictory desired values in scan flip-flops (211 to 275) after the next shift operation (time 132).

For example, if the desired values of scan flip-flops (231, 232, 233, 234, 235, and 215) are set to (0, 1, 1, 1, 1, and 1), respectively, and the desired values of scan flip-flops (252, 253, 254, 255, and 275) are set to (0, 1, 1, 1, and 1) at the rising edge of clock C at time 122, at the next shift operation (time 132) scan flip-flops (231, 232, 233, 234, and 235) may become (1, 1, 1, 1, and 1), respectively, and scan flip-flops (251, 252, 253, 254, and 255) may become (0, 1, 1, 1, and 1) and a delay test may be executed with desired test pattern. A process for determining a test pattern by verifying values set will be discussed later.

In some cases, a desired test pattern may not be executed because set values before a delay test may conflict with set values on a subsequent shift operation to execute the test. In such a case, it may be desirable that a scan test circuit be modified so as to facilitate a desired test pattern using the delay test of the present method. Such a modification is illustrated in scan test circuit 400 of FIG. 4.

Referring once again to FIG. 4, scan test circuit 400 may be used to implement a delay test on a RAM 441. Scan test circuit 400 may include scan flip-flops (411-415, 431-435, 451-455, and 471-475) and normal operation circuits (421 and 461) that may generate inputs to and receive outputs from RAM 441 to be tested.

Scan flip-flops (431 to 435 and 451 to 455) may be considered boundary scan flip-flops.

By providing a first scan chain in the order of (411-431-412-432-413-433-414-434-415-435) and a second scan chain in the order of (471-451-472-452-473-453-474-454-475-455), a two cycle test may be performed with independent values set for each of the two cycles. The independent values may be initially set in a shift operation mode. In this way, RAM 441 may be tested without dependence of a second executed pattern on a first executed pattern.

First and second sets of values (patterns) may be alternatively set in scan flip-flops (431 to 435 and 451 to 455) and scan flip-flops (411 to 415 and 471 to 475), respectively. RAM 441 may first operate in accordance with first values (a first pattern) set in scan flip-flops (431 to 435 and 451 to 455). On a subsequent shift operation, second values (a second pattern) in scan flip-flops (411 to 415 and 471 to 475) may be read into scan flip-flops (431 to 435 and 451 to 455) and RAM 441 may operate in accordance with the second values. In this way, RAM 441 may be tested in accordance with first and second patterns, which may be independent.

Scan flip-flop 431 may provide an output to a write data input WD[0] of RAM1 441. Scan flip-flop 432 may provide an output to a write data input WD[1] of RAM1 441. Scan flip-flop 433 may provide an output to a write address input WA[0] of RAM1 441. Scan flip-flop 434 may provide an output to a write address input WA[1] of RAM1 441. Scan flip-flop 435 may provide an output to a write enable input WE of RAM1 441. Scan flip-flop 453 may provide an output to a read address input RA[0] of RAM1 441. Scan flip-flop 454 may provide an output to a read address input RA[1] of RAM1 441. Scan flip-flop 455 may provide an output to a read enable input RE of RAM1 441.

Referring to FIG. 4 in conjunction with FIG. 1, in a delay test, first data may be written into a memory cell and then opposite data may then be written into the memory cell. If write data (WD[1]-WD[0]) of (10) is written into an address (WA[1]-WA[0]) of (11) followed by write data (WD[1]-WD[0]) of (11) written to the same address to conduct a delay test, a first and second test values may be alternatively scan-shifted in synchronism with a rising edge of clock input C so that, at timing 122, scan flip-flops (431, 432, 433, 434, and 435) may output (0, 1, 1, 1, and 1) (a first test value), respectively. This may allow write data of (10) to be written into address (11). At this time, scan flip-flops (411, 412, 413, 414, and 415) may output (1, 1, 1, 1, and 1) (a second test value), respectively. Also at this time, scan flip-flops (471, 472, 473, 474, and 475) may output (0, 1, 1, 1, and 1), respectively.

A shift operation may continue such that a second test value may be scan-shifted in synchronism with a rising edge of clock input C so that, at timing 132, scan flip-flops (431, 432, 433,434, and 435) may output (1, 1, 1, 1, and 1), respectively. In this way, write data of (11) to be written into address (11). Also, at timing 132, scan flip-flops (451, 452, 453, 454, and 455) may output (0, 1, 1, 1, and 1), respectively.

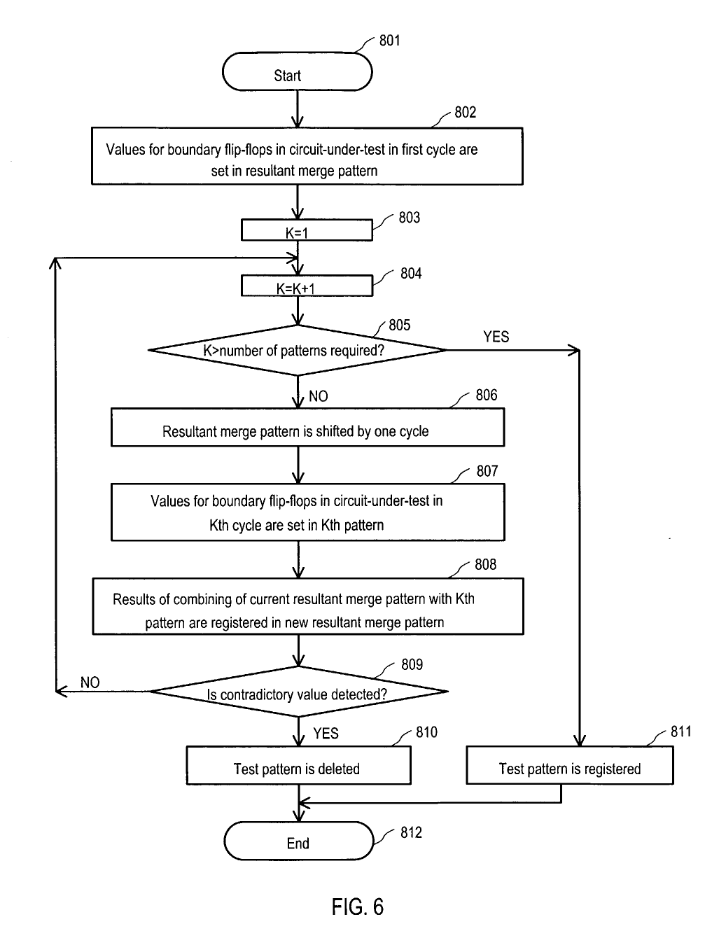

Referring now to FIG. 6, a flow chart for a method of generating a test pattern for a typical circuit according to an embodiment is set forth.

First, after a start operation at step 801, the process may proceed to setting values for boundary flip-flops of a circuit-under-test in a first cycle as a resultant merge pattern in step 802. At step 802, the first test pattern for testing the circuit-under-test may be registered as a pattern being generated. This pattern being generated may be referred to as a “resultant merge pattern.”

Next, at step 803 a variable K may be set to one. K may indicate a number of patterns generated.

After set 803 the method of generating a test pattern may enter a process flow for generating a second and subsequent patterns. At step 804, variable K may be incremented by one.

Next, a determination as to whether K exceeds the number of patterns required may be conducted in step 805. K being greater than the required number of patterns may indicate that the patterns required have been generated. In this case, the process may proceed to a test pattern registration step 811 and the patterns may be registered as final test patterns.

However, if, in step 805, the required number of patterns has not been exceeded, the process may proceed to a step 806 for shifting the resultant merge pattern by one cycle backward.

Because no value may be set for the first flip-flop in a shift path at this point in time, an unrestricted value may be set.

According to the embodiments, because values used in the test may be continuously shifted and a first pattern may be shifted by one cycle and used in a second pattern, the first pattern may place constrains on a value that may be generated for the second pattern.

Thus, it may be required to shift and analyze a pattern from a previous cycle to determine whether the pattern is consistent with desired values required in the present cycle. At step 806, patterns that can be tested by shifting by K-1 cycle on a continuous basis may be stored in the resultant merge pattern.

At step 807 values may be set for the boundary flip-flops of the circuit-under-test in the K^{th} pattern in the K^{th} cycle. The set values for the boundary flip-flops of the circuit-under-test in the K^{th} cycle may be set as the K^{th} pattern. Then, the process may proceed to step 808 and the results of operation for combining the present resultant merge pattern with the K^{th} pattern may be registered.

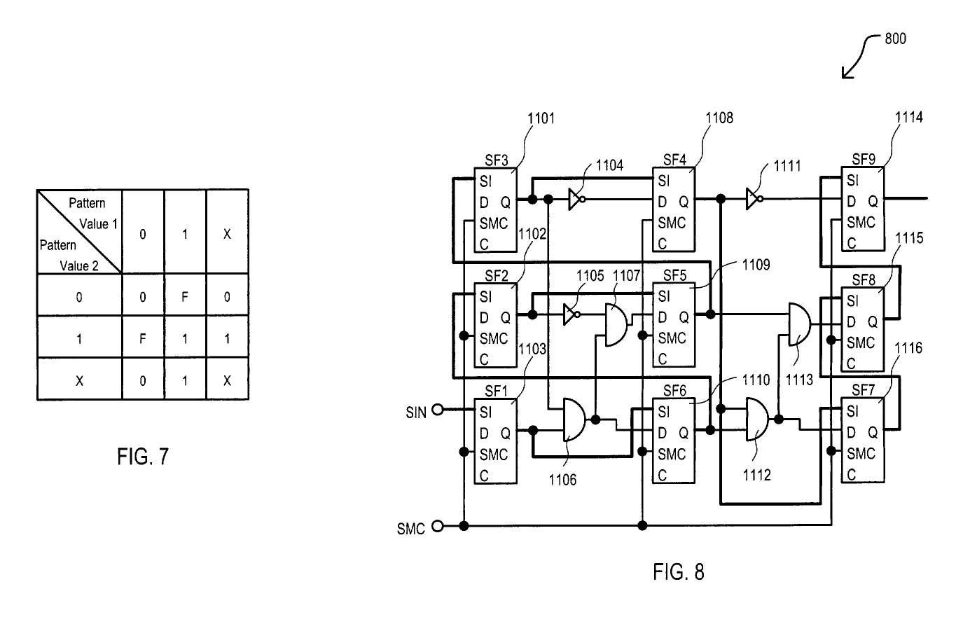

At step 808, a combining operation to check if the resultant merge pattern (representing values set by the K-^{th} pattern) and the K^{th} pattern from step 807 include conflicts with respect to each other. A calculation used in this combining operation is illustrated in a tabular form in FIG. 7.

Referring now to FIG. 7, pattern value 1 and pattern value 2 may represent values for the resultant merge pattern and values for the K^{th} pattern, respectively. Symbol X may represent a “don't care” value and F may represent conflicting values between the respective patterns. Essentially, the calculation may determine if there is a conflict in a set value of a previous test pattern already shifted and used and a set value in a new test pattern loaded into a scan flip-flop on a subsequent clock cycle. The table indicates respective pattern values for the same scan flip-flop.

In response to results of the combining operation at step 808, a determination as to whether any conflicting values are found may be made a step 809. If at least one conflicting value is found resulting from the combining operation at step 808, the process may proceed to step 810 and the previously generated test patterns may be deleted.

In this case, test pattern generation may be redone. However, if no conflicting value is found at step 809, the process may proceed to step 804 and the test pattern generation may be continued. The above-described process may be repeated until the required number of patterns have been generated. After the required number of patterns have been generated (K >number of patterns required), the process may proceed to step 811 and the test patterns may be registered. The process may end at step 812.

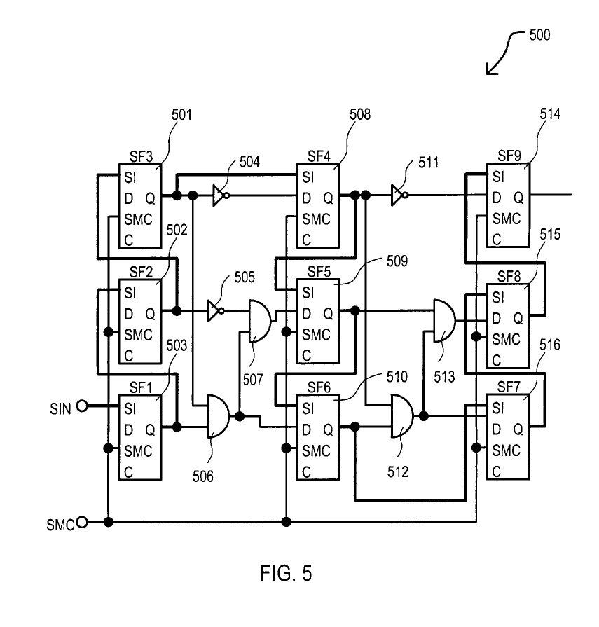

The method for generating a test pattern based on the flowchart in FIG. 6 will now be described with respect to the circuit 500 set forth in FIG. 5.

Circuit 500 may include scan flip-flops (501, 502, 503, 508, 509, 510, 514, 515, and 516), inverters (504, 505, and 511), and AND gates (506, 507, 512, and 513). Scan flip-flops (501, 502, 503, 508, 509, 510, 514, 515, and 516) may form a scan chain in the order of (503-502-501-508-509-510-516-515- 514). Scan chains may be illustrated by bold signal lines. Scan flip-flop 501 may provide an output Q to an input of inverter 504 and an input of AND gate 506. Inverter 504 may provide a data input D to scan flip-flop 508. Inverter 505 may receive an output Q from scan flip-flop 502 and provide an output to an input of AND gate 507. Scan flip-flop 503 may provide an output Q to an input of AND gate 506. AND gate 506 may provide an output to an input of AND gate 507 and a data input D to scan flip-flop 510. AND gate 507 may provide an output to a data input D of scan flip-flop 509. Scan flip-flop 508 may provide an output Q to an input of inverter 511 and an input of AND gate 512. Inverter 511 may provide an output to a data input D of scan flip-flop 514. AND gate 512 may receive an input from an output Q of scan flip-flop 510 and may provide an output to an input of AND gate 513 and a data input D of scan flip-flop 516. AND gate 513 may provide an output to a data input D of scan flip-flop 515.

The following example illustrates a delay test conducted on a path from scan flip-flop 510 via AND gates (512 and 513) to flip-flop 515 in circuit 500 for a case where scan flip-flop 510 has a value changed from zero to one. In this case, a logic value of one may be initially set for scan flip-flops (508 and 509) and a value of logic zero may be set for scan flip-flop 510 in a first cycle of the test and a value of logic one may be set for scan flip-flops (508, 509, and 510) in a second cycle of the test. In this example, scan flip-flops (508, 509, and 510) may be considered boundary flip-flops as they may apply outputs Q to a circuit-under-test. A circuit-under-test may be AND gates (512 and 513).

Tables 1 to 3 illustrate the test pattern generation method. Reference numbers (SF1, SF2, SF3, SF4, SF5, SF6, SF7, SF8, and SF9) indicate scan flip-flops (503, 502, 501, 508, 509, 510, 516, 515, and 514), respectively.

Referring now to Table 1, in a first cycle, SF4 (scan flip-flop 508), SF5 (scan flip-flop 509), and SF6 (scan flip-flop 510) may respectively set to logic values (1, 1, and 0). In a second cycle, values for causing a logic change to propagate along the desired test path may be set. Thus, SF4 (scan flip-flop 508), SF5 (scan flip-flop 509), and SF6 (scan flip-flop 510) may respectively set to logic values (1, 1, and 1). At this time, SF8 (scan flip-flop 515) may be set to a logic value (0). It is desired that SF8 (scan flip-flop 515) be set to a logic value zero in order to allow a changing logic value to propagate through the delay path being tested.

TABLE 1

| Pattern | | | | | | | | | |
|---|---|---|---|---|---|---|---|---|---|
| number | SF1 | SF2 | SF3 | SF4 | SF5 | SF6 | SF7 | SF8 | SF9 |
| 1 | x | x | x | 1 | 1 | 0 | x | x | x |
| 2 | x | x | x | 1 | 1 | 1 | x | 0 | x |

Table 2, illustrates a resultant merge pattern in each cycle illustrated in each cycle shown in the flowchart in FIG. 6. After the completion of the operation at step 802 (FIG. 6), the resultant merge pattern for the first pattern may be the first cycle pattern itself and may therefore be illustrated in Table 2 as merge count 1.

TABLE 2

| Merge | | | | | | | | | |
|---|---|---|---|---|---|---|---|---|---|
| count | SF1 | SF2 | SF3 | SF4 | SF5 | SF6 | SF7 | SF8 | SF9 |
| 1 | x | x | x | 1 | 1 | 0 | x | x | x |
| 2 | x | x | x | 1 | 1 | 1 | 0 | 0 | x |

Then, values provided may be shifted by one cycle at step 806 (FIG. 6) and values for SF4 (scan flip-flop 508), SF5 (scan flip-flop 509), and SF6 (scan flip-flop 510) may be shifted and provide values for SF5 (scan flip-flop 509), SF6 (scan flip-flop 510), and SF7 (scan flip-flop 516), respectively. The shifted values may be combined with values shown in the second pattern in Table 1 (values for the second cycle) and values shown as merge count 2 may be provided without a conflict.

In this way, test values may be set so that a shift operation mode may be used to generate values in a second test execution clock cycle become values illustrated in the row of merge count 2 in Table 2.

Table 3 may illustrate set values set in scan flip-flops desired in the first test execution clock cycle.

TABLE 3

| SF1 | SF2 | SF3 | SF4 | SF5 | SF6 | SF7 | SF8 | SF9 |
|---|---|---|---|---|---|---|---|---|
| x | x | 1 | 1 | 1 | 0 | 0 | x | x |

The above description has shown how a test pattern may be generated for one particular scan chain path. The method of test pattern generation may be applicable to various other scan chain path configurations, however.

FIG. 8 is a circuit diagram of a circuit 800 including a scan chain. Circuit 800 may be the same as circuit 500 of FIG. 5 with the exception of the path of the scan chain. Circuit 800 may include scan flip-flops (1101, 1102, 1103, 1108, 1109, 1110, 1114, 1115, and 1116), inverters (1104, 1105, and 1111), and AND gates (1106, 1107, 1112, and 1113). Scan flip-flops (1101, 1102, 1103, 1108, 1109, 1110, 1114, 1115, and 1116) may form a scan chain in the order of (1103-1110-1102-1109-1101-1108-1116-1115- 1114). Scan chains may be illustrated by bold signal lines.

The following example illustrates a delay test conducted on a path from scan flip-flop 1110 via AND gates (1112 and 1113) to flip-flop 1115 in circuit 800 for a case where scan flip-flop 1110 has a value changed from zero to one. In this example, scan flip-flops (1108, 1109, and 1110) may be considered boundary flip-flops as they may apply outputs Q or receive inputs from a circuit-under-test. A circuit-under-test may be AND gates (1112 and 1113).

Because scan flip-flops (1101, 1102, 1103, and 1116) precede the above boundary scan flip-flops, such flip-flops may not be considered boundary flip-flops for the particular test, and any values may be set for them in the two consecutive cycles after the start of the test.

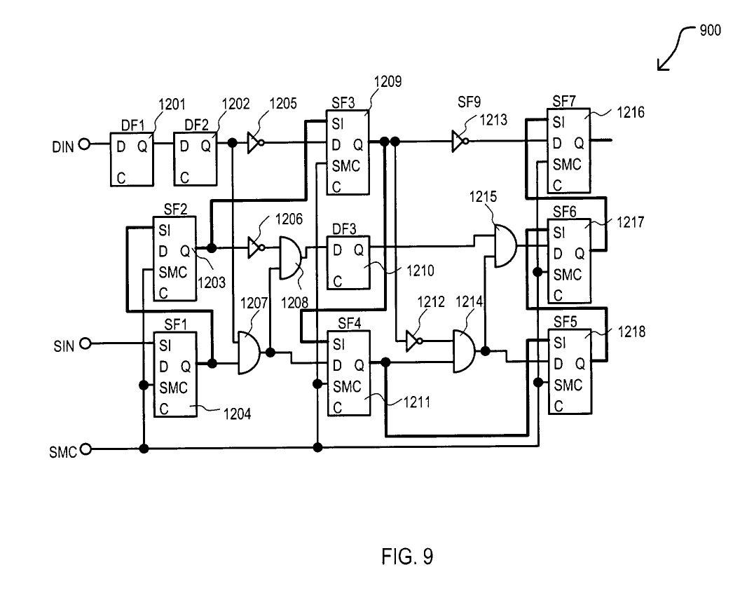

Referring now to FIG. 9, a circuit schematic diagram of a circuit 900 according to an embodiment is set forth. Circuit 900 may include flip-flops (1201, 1202, and 1210). Flip-flops (1201, 1202, and 1210) may be normal flip-flops. Circuit 900 may also include scan flip-flops (1203, 1204, 1209, 1211, 1216, 1217, and 1218), inverters (1205, 1206, 1212, and 1213) and AND gates (1207, 1208, 1214, and 1215).

Circuit 900 may include a scan chain in the order of (1204-1203-1209-1211-1218-1217-1216). The scan chain may be illustrated by bold signal lines.

Flip-flop 1201 may receive a data input signal DIN at a data input D and provide an output Q to a data input of flip-flop 1202. Flip-flop 1202 may provide an output Q to an input of inverter 1205 and AND gate 1207. Scan flip-flop 1203 may provide an output to an input of inverter 1206. Scan flip-flop 1204 may provide an output Q to an input of AND gate 1207. AND gate 1207 may provide an output to an input of AND gate 1208 and a data input D of scan flip-flop 1211. AND gate 1208 may provide an output to a data input D of flip-flop 1210. Scan flip-flop 1209 may provide an output Q to an input of inverters (1212 and 1213). Inverter 1213 may provide an output to a data input D of scan flip-flop 1216. Inverter 1212 may provide an output to an input of AND gate 1214. Scan flip-flop 1211 may provide an output to an input of AND gate 1214. AND gate 1214 may provide an output to an input of AND gate 1215 and a data input D of scan flip-flop 1218.

Tables 4 to 6 illustrate a test pattern generation method for a stuck-at-zero fault in which an output Q of flip-flop 1210 in circuit 900 is stuck at zero. In Tables 4 to 6, scan flip flops (1204, 1203, 1209, 1211, 1218, 1217, and 1216) are represented by symbols SF1, SF2, SF3, SF4, SF5, SF6, and SF7, respectively. Data input DIN may be an external input terminal connected to data input D of flip-flop 1201. A virtual scan flip-flop, not illustrated in FIG. 9, may be represented by SF0 and may provide an scan input signal SIN to a scan input SI of scan flip-flop 1204 and may be used in an explanation of a shift operation.

TABLE 4

| Pattern number | SF1 | SF2 | SF3 | SF4 | SF5 | SF6 | SF7 | DIN |
|---|---|---|---|---|---|---|---|---|
| 1 | x | x | x | x | x | x | x | 1 |
| 2 | 1 | 0 | x | x | x | x | x | x |
| 3 | x | x | 0 | 1 | x | x | x | x |

TABLE 5

| Merge Count | SF1 | SF2 | SF3 | SF4 | SF5 | SF6 | SF7 |
|---|---|---|---|---|---|---|---|
| 1 | x | x | x | x | x | x | x |
| 2 | 1 | 0 | x | x | x | x | x |
| 3 | x | 1 | 0 | 1 | x | x | x |

TABLE 6

| SF0 | SF1 | SF2 | SF3 | SF4 | SF5 | SF6 | SF7 |
|---|---|---|---|---|---|---|---|
| 1 | 0 | 1 | x | x | x | x | x |

Values for scan flip-flops may be set in the order of pattern numbers illustrated in Table 4. In a first cycle flip-flop 1201 may be a logic “1”. In a second cycle, the output Q of flip-flop 1202 may become a logic “1”, the outputs Q of SF1 (scan flip-flop 1204) and SF2 (scan flip-flop 1203) may become a logic “1” and logic “0”, respectively. In this way, a value of logic “1” may propagate to flip-flop 1210.

In a third clock cycle, the output Q of DF3 (flip-flop 1210) may become a logic “1”, and the outputs Q of SF3 (scan flip-flop 1209) and SF4 (scan flip-flop 1211) may become a logic “0” and a logic “1”, respectively. Thus, a data input D to SF6 (scan flip-flop 1217) from a normal operation circuit (such as AND gate 1215) may become a logic “1”. However, if the output Q of flip-flop 1210 has a stuck-at-zero fault, the input to SF6 (scan flip-flop 1217) may become a logic “0”. In this way, a fault may be detected.

Whether a test may be conducted may be determined by performing shift operations continuously using the method illustrated in the flowchart in FIG. 6 after the test is started. Table 5 illustrates a resultant merge pattern in each individual cycle. Because the first pattern (merge count 1) has no set values for the scan flip-flops (SF1 to SF7), the resultant merge pattern for these scan flip-flops (SF1 to SF7) may be don't cares.

The above-mentioned values may be shifted by one cycle and an operation for combining these values with values in the second pattern may be performed. In this way, values for the second merge count (merge count 2) may result. Then, these values may be further shifted by one cycle and an operation for combining these values with values in the third pattern may be performed. In this way, values for the third merge count (merge count 3) may result. Because no conflict has arisen in the process of obtaining the resultant merge pattern (merge count 3) of the third pattern, the values may be continuously shifted so that values for scan flip flops become the values shown as merge count 3 in the third clock cycle after the test is started. Table 6 shows set values for the scan flip-flops (SF0 to SF7) in the clock cycle in which the test is started.

Boundary scan flip-flops may be scan flip-flops providing or receiving logic values to or from a circuit under test.

A scan test circuit according to the present embodiments configured and implemented as described above may have the following advantages.

A first advantage can include conducting a delay test without circuit overhead and a process for setting values with normal circuits being in a normal operation may be performed with reduced complexity. Complexity may be reduced by providing a pattern generation method or circuit configuration method that may set values required for the test simply by performing continuous shift operations.

A second advantage can include a sequence circuit that may be tested without an excessively complicated setting of normal circuits. This may be accomplished by using a pattern generation method or circuit configuration method that may set values required for the test by performing continuing shift operations.

It is understood that the embodiments described above are exemplary and the present invention should not be limited to those embodiments. Specific structures should not be limited to the described embodiments.

Thus, while the various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A scan test method for a scan chain of a plurality of scan flip-flops including a first plurality of boundary scan flip-flops, comprising the steps of:
setting initial test values in the first plurality of boundary scan flip-flops through the scan chain in a shift operation mode so that the initial test values are applied to a circuit under test in a first clock cycle; and
setting next test values in the first plurality of boundary scan flip-flops in the shift operation mode so that the next test values are applied to the circuit under test in a next clock cycle wherein the initial test values and the next test values are set in successive clock cycles and are a test pattern for conducting one test.

2. The scan test method according to claim 1, further including the step of:
reading a test result into a second plurality of boundary scan flip-flops from the circuit under test in a normal operation mode.

3. The scan test method according to claim 2, further including the step of:
shifting data values out of the second plurality of boundary scan flip-flops in the shift operation mode.

4. The scan test method according to claim 1, wherein:
the initial test values do not conflict with the next test values.

5. The scan test method according to claim 1, wherein:
the plurality of scan flip-flops read data from a scan input in synchronism with a first clock edge in the shift operation mode and read data from a data input in synchronism with the first clock edge in a normal operation mode.

6. The scan test method according to claim 5, wherein:
the one test is conducted and a test result is read into a second plurality of boundary flip-flops with only one clock cycle executed in the normal operation mode.

7. The scan test method according to claim 1, wherein:
the scan test method tests a semiconductor memory device.

8. A scan test method for a scan chain including first and second scan flip-flops and first and second boundary scan flip-flops wherein the first scan flip-flop is coupled in the scan chain to provide a first scan flip-flop output to a first boundary scan flip-flop input of the first boundary scan flip-flop and the second scan flip-flop is coupled in the scan chain to provide a second scan flip-flop output to a second boundary scan flip-flop input of the second boundary scan flip-flop, comprising the steps of:
setting initial test values in the first and second boundary scan flip-flops and next test values in the first and second scan flip-flops through the scan chain in a shift operation mode so that the initial test values are applied to a circuit under test in a first clock cycle; and
setting the next test values in the first and second boundary scan flip-flops in the shift operation mode so that the next test values are applied to the circuit under test in a next clock cycle wherein the initial test values and the next test values are set in successive clock cycles and are a test pattern for conducting one test.

9. The scan test method according to claim 8, further including the step of:
reading a test result into a third boundary scan flip-flop from the circuit under test in a normal operation mode.

10. The scan test method according to claim 9, further including the step of:
shifting a data value out of the third boundary scan flip-flop in the shift operation mode.

11. The scan test method according to claim 8, wherein:
In a shift operation, the first boundary scan flip-flop provides data to a second scan flip-flop input of the second scan flip-flop.

12. The scan test method according to claim 8, wherein:
the first boundary scan flip-flop reads data from the first boundary scan flip-flop input in synchronism with a first clock edge in the shift operation mode and reads data from a first boundary scan flip-flop data input in synchronism with the first clock edge in a normal operation mode;
the second boundary scan flip-flop reads data from the second boundary scan flip-flop input in synchronism with the first clock edge in the shift operation mode and reads data from a second boundary scan flip-flop data input in synchronism with the first clock edge in the normal operation mode;
the first scan flip-flop reads data from a first scan flip-flop input in synchronism with the first clock edge in the shift operation mode and reads data from a first scan flip-flop data input in synchronism with the first clock edge in the normal operation mode; and
the second scan flip-flop reads data from a second scan flip-flop input in synchronism with the first clock edge in the shift operation mode and reads data from a second scan flip-flop data input in synchronism with the first clock edge in the normal operation mode.

13. The scan test method according to claim 8, wherein:
the one test is conducted and a test result is read into a third boundary flip-flop with essentially only one clock cycle executed in the normal operation mode.

14. The scan test method according to claim 8, wherein:
the scan test method tests a semiconductor device.

15. A scan test method for a scan chain of a plurality of scan flip-flops including a first plurality of boundary scan flip-flops and the plurality of scan flip-flops operate in a shift operation mode and a normal operation mode, comprising the steps of:
setting initial test values in the first plurality of boundary scan flip-flops through the scan chain in the shift operation mode so that the initial test values are applied to a circuit under test in a first clock cycle;
setting next test values in the first plurality of boundary scan flip-flops in the shift operation mode so that the next text values are applied to the circuit under test in a next clock cycle wherein the initial test values and the next test values are set in successive clock cycles and are a test pattern for conducting one test; and
reading a test result from the circuit under test into a second plurality of boundary scan flip-flops in a normal operation mode wherein the one test is conducted with essentially only one clock cycle executed in the normal operation mode.

16. The scan test method according to claim 15, wherein:
the next test values depend on at least a portion of the initial test values.

17. The scan test method according to claim 15, wherein:
the next test values are set in the first plurality of boundary scan flip-flops independent of the initial test values.

18. The scan test method according to claim 15, further including the step of:
shifting data values out of the second plurality of scan flip-flops in the shift operation mode.

19. The scan test method according to claim 15, wherein:
the scan test method tests a circuit on an integrated circuit.

20. The scan test method according to claim 15, wherein:
a data input to at least one scan flip-flop receives data from an output from a normal flip-flop.
